(19) United States
(12) Patent Application Publication
(10) Pub. No.: US 2013/0118403 A1
(43) Pub. Date: May 16, 2013

(54) CHEMICAL BATH DEPOSITION SYSTEM

(71) Applicants: Shih-Wei Lee, Kaohsiung City (TW); Lung-Chieh Wang, Taichung City (TW); Chih-Lung Lin, Chiayi County (TW)

(72) Inventors: Shih-Wei Lee, Kaohsiung City (TW); Lung-Chieh Wang, Taichung City (TW); Chih-Lung Lin, Chiayi County (TW)

(21) Appl. No.: 13/467,068

(22) Filed: May 9, 2012

(30) Foreign Application Priority Data
Nov. 14, 2011 (TW) 100141487

(51) Int. Cl. B05C 3/09; B05C 11/00

(52) U.S. Cl. 118/712; 118/610; 118/73

(57) ABSTRACT

A chemical bath deposition system is used for forming a buffer layer on a back electrode substrate having a photoelectric transducing layer. The chemical bath deposition system includes a chemical bath tank, a chemical-solution purification device, and a dosing device. The chemical bath tank is used for storing a buffer-layer solution including cation and anion. The cation is adapted to react with the anion to form the buffer layer when the back electrode substrate is immersed in the buffer-layer solution. The chemical-solution purification device is communicated with the chemical bath tank for removing residual cation to obtain a purified solution after the cation reacts with the anion to form the buffer layer. The dosing device is for performing compensation of the cation according to a component ratio of a purified solution.

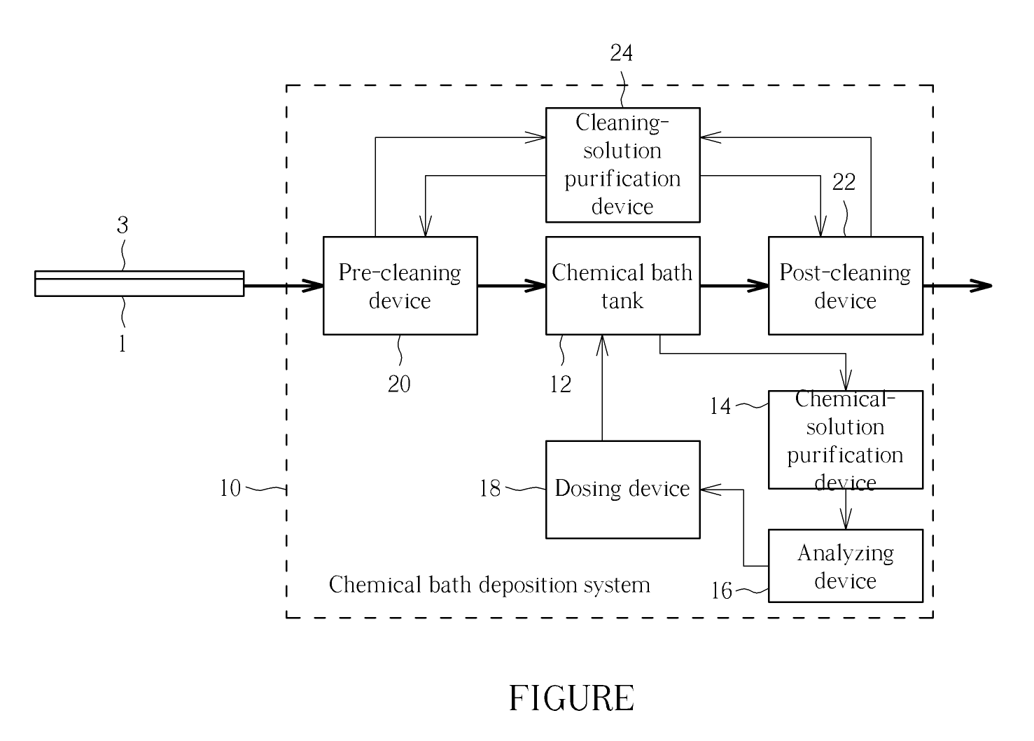

### BACKGROUND OF THE INVENTION

1. Field of the Invention

The present invention relates to a chemical bath deposition system, and more specifically, to a chemical bath deposition system utilizing a chemical-solution purification device to purify a reacted buffer-layer solution.

2. Description of the Prior Art

In a conventional solar battery manufacturing process, a common method of forming a buffer layer on a solar battery substrate involves utilizing a chemical bath deposition process to immerse the solar battery substrate with a photoelectric transducing layer deposited thereon in a buffer-layer solution of a chemical bath tank. When the solar battery substrate is immersed in the buffer-layer solution, a buffer layer is deposited on the photoelectric transducing layer via combination of cation (e.g. zinc ion or cadmium ion) and anion (e.g. sulfur ion) in the buffer-layer solution.

Furthermore, for improving the forming quality of the buffer layer, in this method, a cleaning solution could be utilized to clean the solar-battery substrate before and after the buffer layer is formed, so as to prevent dust from heaping on the solar-battery substrate.

However, this method may cause a large amount of cleaning waste solution and chemical waste solution. Improper recycling may cause unnecessary waste and serious pollution. US patent no. 7541067 discloses the design of additionally disposing a solution tank with a solution analyzing function to be communicated with the chemical bath tank. Accordingly, a component ratio of a reacted chemical solution in the chemical bath tank could be analyzed by a conventional analyzing method (e.g. a classic titration method), and then the reacted chemical solution could be reduced from a reacted state to an unreacted state according to the component ratio by a component dosing method. In such a manner, the reduced chemical solution could be guided back into the chemical bath tank so as to achieve the recycling purpose. However, since the reaction of the reacted chemical solution is still continued, the aforesaid design could not precisely analyze the final component ratio of the reacted chemical solution. That is, the aforesaid design could not precisely reduce the reacted chemical solution back to its original state, so that the forming quality of the subsequent buffer layer may be influenced.

### SUMMARY OF THE INVENTION

The present invention provides a chemical bath deposition system for forming a buffer layer on at least one back electrode substrate having a photoelectric transducing layer. The chemical bath deposition system includes a chemical bath tank, a chemical-solution purification device, and a dosing device. The chemical bath tank is for storing a buffer-layer solution. The buffer-layer solution includes a cation and an anion. The cation is used for reacting with the anion to form the buffer layer on the photoelectric transducing layer when the back electrode substrate is placed in the chemical bath tank to be immersed in the buffer-layer solution. The chemical-solution purification device is communicated with the chemical bath tank for removing residual cation to obtain a purified solution after the cation reacts with the anion to form the buffer layer. The dosing device is for performing compensation of the cation according to a component ratio of the purified solution.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The FIGURE is a functional block diagram of a chemical bath deposition system according to an embodiment of the present invention.

### DETAILED DESCRIPTION

Please refer to the FIGURE, which is a functional block diagram of a chemical bath deposition system 10 according to an embodiment of the present invention. The chemical bath deposition system 10 is used for forming a buffer layer on at least one back electrode substrate 1 (one shown in the FIGURE) having a photoelectric transducing layer 3. The design of forming the back electrode substrate 1 and the photoelectric transducing layer 3 is commonly seen in the prior art. In brief, the substrate of the back electrode substrate 1 could be a soda-lime glass, and the back electrode of the back electrode substrate 1 could be made of molybdenum material, tantalum material, titanium material, vanadium material, or zirconium material. The photoelectric transducing layer 3 could be a CIGS (copper indium gallium selenide) structure, but not limited thereto. That is, the back electrode substrate 1 and the photoelectric transducing layer 3 could also be made of other material commonly applied to a solar battery. To be noted, the present invention could also form a buffer layer on plural back electrode substrates respectively in a batch manner for further increasing the productive capacity of the chemical bath deposition system 10.

As shown in the FIGURE, the chemical bath deposition system 10 includes a chemical bath tank 12, a chemical-solution purification device 14, an analyzing device 16, and a dosing device 18. The chemical bath tank 12 is used for storing a buffer-layer solution. The buffer-layer solution could include cation and anion. In this embodiment, the cation is selected from at least one of a zinc ion, a cadmium ion, a mercury ion, an aluminum ion, a gallium ion, and an indium ion, and the anion is selected from at least one of an oxygen ion, a sulfur ion, a selenium ion, and a hydroxide ion. Accordingly, the cation could be used for reacting with the anion to form a corresponding buffer layer (e.g. CdS, ZnS, ZnO, CdSe, ZnSe, Zn(OH)₂, Cd(OH)₂, CdZnS or In₂S₃) on the photoelectric transducing layer 3. The chemical-solution purification device 14 is communicated with the chemical bath tank 12. As a result, after a buffer layer forming process is completed, the buffer-layer solution could be guided into the chemical-solution purification device 14. The chemical-solution purification device 14 is used for removing residual cation to generate a purified solution after the cation reacts with the anion to form the buffer layer. It should be mentioned that the purified solution does not include the cation needed to form the buffer layer. The analyzing device 16 is used for analyzing the purified solution to generate a corresponding component ratio. The dosing device 18 is used for performing compensation of the cation according to the component ratio generated from the analyzing device 16. In the present invention, the purified solution could be directly guided into the chemical bath tank 12 before the dosing process is performed, or be guided back into the chemical bath tank 12 after the cation dosing process is performed on the purified solution in a mixing tank (not shown in the FIGURE).

The design of utilizing the chemical solution in the chemical bath tank 12 to forma corresponding compound layer could be realized by a conventional chemical bath deposition method. In brief, after the back electrode substrate 1 is immersed in the chemical solution including metal cation (e.g. zinc ion or cadmium ion) and anion (e.g. an oxygen ion, a sulfur ion, a selenium ion, and a hydroxide ion), via appropriately adjusting the temperature and acid-base value of the chemical solution, the metal cation could react with the anion so as to make the corresponding compound layer deposit on the back electrode substrate 1 uniformly.

Furthermore, for improving the forming quality of the buffer layer and making the chemical bath deposition system 10 have a cleaning waste solution recycling function, as shown in the FIGURE, the chemical bath deposition system 10 could further include a pre-cleaning device 20, a post-cleaning device 22, and a cleaning-solution purification device 24. The pre-cleaning device 20 is used for cleaning the back electrode substrate 1 before the back electrode substrate 1 is placed in the chemical bath tank 12, so as to prevent dust from heaping on the photoelectric transducing layer 3. The post-cleaning device 22 is used for cleaning the back electrode substrate 1 after the back electrode substrate 1 is displaced from the chemical bath tank 12, so as to prevent dust from heaping on the back electrode substrate 1. The cleaning-solution purification device 24 is communicated with the pre-cleaning device 20 and the post-cleaning device 22 for purifying the cleaning solution generated by the pre-cleaning device 20 and the post-cleaning device 22 after the pre-cleaning device 20 and the post-cleaning device 22 clean the back electrode substrate 1 and for guiding the purified cleaning solution back into the pre-cleaning device 20 and the post-cleaning device 22, so as to achieve the recycling purpose.

Via the aforesaid design, the chemical bath deposition system 10 could have a chemical-solution recycling function and a cleaning-solution recycling function. More detailed description for the chemical-solution recycling process and the cleaning-solution recycling process of the chemical bath deposition system 10 is provided as follows. In the following description, it is assumed that the ratio of the cation, the anion, a buffering agent, and an ammonia solution in the unreacted buffer-layer solution is 1:3:5:50 and the ratio of the cation, the anion, the buffering agent, and the ammonia solution in the reacted buffer-layer solution is 0.5:2.5:4.5:40 (but not limited thereto).

When the cleaned back electrode substrate 1 is immersed in the buffer-layer solution of the chemical bath tank 12, the cation reacts with the anion in the buffer-layer solution to form the buffer layer on the photoelectric transducing layer 3 of the back electrode substrate 1. For example, if the cation is a cadmium ion and the anion is a sulfur ion, the CdS buffer layer is formed on the photoelectric transducing layer 3 uniformly during the back electrode substrate 1 is immersed in the chemical bath tank 12.

Subsequently, the chemical-solution purification device 14 could purify the limiting reagent (i.e. the cation) in the reacted buffer-layer solution. As mentioned above, the ratio of the cation, the anion, the buffering agent, and the ammonia solution in the reacted buffer-layer solution is 0.5:2.5:4.5:40. Thus, the chemical-solution purification device 14 could decrease the cation from the ratio of 0.5 down to 0 by a chemical purification method, so as to obtain a purified solution in which the buffer-layer forming reaction has been stopped. The aforesaid chemical purification method utilized by the chemical-solution purification device 14 is commonly seen in the prior art, such as a thermal processing method, an acid-base processing method, or an oxidation-reduction method, and the related description is omitted herein. In other words, in this embodiment, the chemical-solution purification device 14 is selected from at least one of a thermal processing device, an acid-base processing device, and an oxidation-reduction device.

After the buffer-layer solution is purified, the analyzing device 16 could analyze the purified solution. At this time, as mentioned above, the analyzing device 16 could precisely analyze that the ratio of the cation, the anion, the buffering agent, and the ammonia solution in the reacted buffer-layer solution is 0:2.5:4.5:40 since the buffer-layer forming reaction in the purified solution has been stopped. Next, the dosing device 18 could perform compensation of the cation on the purified solution according to the aforesaid component ratio (i.e. 0:2.5:4.5:40) analyzed by the analyzing device 16, so as to reduce the ratio of the cation, the anion, the buffering agent, and the ammonia solution in the purified solution from 0:2.5:4.5:40 back to 1:3:5:50. In such a manner, the chemical bath deposition system 10 could continue to perform the buffer-layer forming process on the back electrode substrate 1 without additionally supplying a new buffer-layer solution, so that the chemical-solution recycling purpose could be achieved for decreasing the material cost of the solar battery manufacturing process in forming of the buffer layer.

As for the aforesaid chemical analyzing method utilized by the analyzing device 16, it is commonly seen in the prior art, such as a classic titration method, an automatic titration method, an oxidation-reduction titration method, an acid-base titration method, a column-chromatography titration method, an atomic-absorption-spectrometry analyzing method, or an ultraviolet-visible-spectrometry analyzing method, and the related description is therefore omitted herein. In other words, in this embodiment, the analyzing device 16 could be selected from at least one of a classic titration device, an automatic titration device, an oxidation-reduction titration device, an acid-base titration device, a column-chromatography titration device, an atomic-absorption-spectrometry analyzing device, and an ultraviolet-visible-spectrometry analyzing device. To be noted, the analyzing device 16 could selectively analyze the purified solution by an online analyzing method or an off-line sampling method.

Furthermore, after the pre-cleaning device 20 or the post-cleaning device 22 has cleaned the back electrode substrate 1, the cleaning solution could be guided to the cleaning-solution purification device 24. At this time, the cleaning-solution purification device 24 could utilize a conventional cleaning-solution purification method, such as an ion-exchange resin purification method, a reverse-osmosis membrane dialysis method, an electrolytic purification method, or an oxidation-reduction processing method, to purify the cleaning solution. In other words, the cleaning-solution purification device 24 could be selected from at least one of an ion-exchange resin purification device, a reverse-osmosis membrane dialysis device, an electrolytic purification device, and an oxidation-reduction processing device.

For example, if the cleaning-solution purification device 24 is an ion-exchange resin purification device, the cleaning solution generated by the pre-cleaning device 20 and the post-cleaning device 22 could pass through the resin bed (e.g. combination of an acid resin bed and a base resin bed or an acid-base resin mixing bed) of the cleaning-solution purification device 24 so as to achieve the purpose of residual cation (e.g. cadmium ion or ammonium ion) and anion (e.g. sulfur ion or hydroxide ion) being absorbed by the resin bed. Furthermore, before the cleaning solution passes through the resin bed, the cleaning-solution purification device 24 could further have a filtering apparatus for filtering insoluble matters. Finally, after the cleaning-solution purification device 24 utilizes a conductivity test process to determine that the residual cation and anion in the cleaning solution have been removed, the cleaning-solution purification device 24 could guide the cleaning solution back into the pre-cleaning device 20 and the post-cleaning device 22. In such a manner, the chemical bath deposition system 10 could directly utilize the purified cleaning solution to clean subsequent back electrode substrates instead of additionally supplying a new cleaning solution, so that the cleaning-solution recycling purpose could be achieved for decreasing the solution cost of the solar battery manufacturing process in cleaning the back electrode substrate.

It should be mentioned that the analyzing device 16 could be an omissible device for simplifying the design of the chemical bath deposition system 10. That is, the component ratio could be calculated theoretically instead. As for which method is utilized, it depends on the practical application of the chemical bath deposition system 10.

Compared with the prior art, the present invention utilizes the chemical-solution purification device to purify the buffer-layer solution after the buffer layer is formed. Accordingly, no matter the present invention utilizes the analyzing method or the theoretical calculation method, the chemical bath deposition system of the present invention could obtain the component ratio of the purified solution more precisely since the buffer-layer forming reaction in the purified solution has been stopped. Thus, the dosing device could reduce the reacted buffer-layer solution back to its original state in a component dosing manner, so that the chemical bath deposition system of the present invention could directly utilize the recycled buffer-layer solution to perform the buffer-layer forming process on subsequent back electrode substrates. In such a manner, the chemical-solution recycling purpose could be achieved accordingly and the forming quality of the buffer layer could be further improved, so as to decrease the material cost of the solar battery manufacturing process in forming of the buffer layer. In addition, as mentioned above, the present invention could further utilize additional disposal of the cleaning-solution purification device to make the chemical bath deposition system capable of directly utilize the purified cleaning solution to clean subsequent back electrode substrates. Accordingly, the cleaning-solution recycling purpose could also be achieved for decreasing the solution cost of the solar battery manufacturing process in cleaning the back electrode substrate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chemical bath deposition system for forming a buffer layer on at least one back electrode substrate having a photoelectric transducing layer, the chemical bath deposition system comprising:
a chemical bath tank for storing a buffer-layer solution, the buffer-layer solution comprising a cation and an anion, the cation being used for reacting with the anion to form the buffer layer on the photoelectric transducing layer when the back electrode substrate is placed in the chemical bath tank to be immersed in the buffer-layer solution;
a chemical-solution purification device communicated with the chemical bath tank for removing residual cation to obtain a purified solution after the cation reacts with the anion to form the buffer layer; and
a dosing device for performing compensation of the cation according to a component ratio of the purified solution.

2. The chemical bath deposition system of claim 1 further comprising:
an analyzing device for analyzing the purified solution to generate the component ratio.

3. The chemical bath deposition system of claim 1, wherein the analyzing device is selected from at least one of a classic titration device, an automatic titration device, an oxidation-reduction titration device, an acid-base titration device, a column-chromatography titration device, an atomic-absorption-spectrometry analyzing device, and an ultraviolet-visible-spectrometry analyzing device.

4. The chemical bath deposition system of claim 2, wherein the analyzing device is used for analyzing the purified solution by an online analyzing method or an off-line sampling method.

5. The chemical bath deposition system of claim 1, wherein the cation is selected from at least one of a zinc ion, a cadmium ion, a mercury ion, an aluminum ion, a gallium ion, and an indium ion.

6. The chemical bath deposition system of claim 1, wherein the anion is selected from at least one of an oxygen ion, a sulfur ion, a selenium ion, and a hydroxide ion.

7. The chemical bath deposition system of claim 1, wherein the chemical-solution purification device is selected from at least one of a thermal processing device, an acid-base processing device, and an oxidation-reduction processing device.

8. The chemical bath deposition system of claim 1 further comprising:
a pre-cleaning device for cleaning the back electrode substrate before the back electrode substrate is placed in the chemical bath tank;
a post-cleaning device for cleaning the back electrode substrate after the back electrode substrate is displaced from the chemical bath tank; and
a cleaning-solution purification device communicated with the pre-cleaning device and the post-cleaning device, for purifying a cleaning solution generated by the pre-cleaning device and the post-cleaning device after the pre-cleaning device and the post-cleaning device clean the back electrode substrate and for guiding the cleaning solution back into the pre-cleaning device and the post-cleaning device.

9. The chemical bath deposition system of claim 1, wherein the cleaning-solution purification device is selected from at least one of an ion-exchange resin purification device, a reverse-osmosis membrane dialysis device, an electrolytic purification device, and an oxidation-reduction processing device.

10. The chemical bath deposition system of claim 1, wherein the dosing device is used for performing compensation of the cation after the purified solution is directly guided back into the chemical bath tank.
